(19) United States
(12) Patent Application Publication
(10) Pub. No.: US 2026/0299423 A1
(43) Pub. Date: Oct. 1, 2026

(54) UV LIGHT IRRADIATION APPARATUS AND MOUNTING SYSTEM

(71) Applicant: SHIBAURA MECHATRONICS CORPORATION, Yokohama-shi (JP)

(72) Inventors: Naoki SETO, Yokohama-shi (JP); Kyota KUROIWA, Yokohama-shi (JP); Takuya OHE, Yokohama-shi (JP)

(73) Assignee: SHIBAURA MECHATRONICS CORPORATION, Yokohama-shi (JP)

(21) Appl. No.: 19/578,641

(22) Filed: Mar. 25, 2026

(30) Foreign Application Priority Data
Mar. 25, 2025 (JP) 2025-050670
Jan. 30, 2026 (JP) 2026-014624

(51) Int. Cl. G03F 7/20

(52) U.S. Cl. CPC G03F 7/2004; G03F 7/2008; G03F 7/201

(57) ABSTRACT

According to an embodiment, a UV light irradiation apparatus for irradiating UV light onto a resin film having multiple electronic components adhered to a first surface of the resin film includes a support stage for supporting the resin film; a light source portion irradiating UV light onto a second surface of the resin film opposite the first surface; and a mask portion disposed between the resin film and the light source portion and shielding a part of the UV light.

### CROSS-REFERENCE TO RELATED APPLICATIONS

This application claims the benefit of priority to Japanese Patent Application No. 2025-050670 filed on Mar. 25, 2025, and No. 2026-014624 filed on Jan. 30, 2026, the entire contents of which are incorporated herein by reference.

### BACKGROUND

### Technical Field

One embodiment of the present disclosure relates to a UV light (ultraviolet light) irradiation apparatus and mounting system including the UV light irradiation apparatus.

### Description of the Related Art

Conventionally, a bonding method using bonding members such as wires or bumps has been known as a method for mounting an electronic component such as a semiconductor chip on a substrate and bonding electrodes of the electronic component to electrodes of the substrate. In recent years, with the increasing density of integrated circuits, a method of directly bonding electronic components to electrodes on a substrate without using a bonding member, such as hybrid bonding, has been attracting attention. In such a direct bonding technique, for example, when bonding a semiconductor chip, which is an electronic component, to a semiconductor wafer, which is a substrate, first, a surface activation treatment (e.g., plasma treatment) is performed on the bonding surfaces of the semiconductor chip and the semiconductor wafer to add hydroxyl groups to an insulating film on each bonding surface (terminating the insulating film with hydroxyl groups). Subsequently, the bonding surfaces of the semiconductor chip and the semiconductor wafer are brought into contact with each other to perform a temporary bonding. Finally, heating is performed to firmly bond the insulating films together (main bonding) and to diffusion bond the electrodes together to establish an electrical connection.

For example, in the process of mounting the semiconductor chip on the semiconductor wafer, the semiconductor chip is supplied in a state adhered to an adhesive resin film (adhesive tape) called a wafer sheet, dicing tape, etc. In this case, the semiconductor chip is in a state of being singulated from the semiconductor wafer. Then, various treatments, such as cleaning and surface activation, are performed on the semiconductor chip on the adhesive tape. Subsequently, the adhesive strength of the adhesive tape is reduced, and each semiconductor chip is mounted on another semiconductor chip or semiconductor wafer, which is the mounting target, by a bonding apparatus. The adhesive strength of the adhesive tape is reduced by curing an adhesive layer on the surface. Usually, a UV-curable resin is used as the material for the adhesive layer. In other words, by irradiating the adhesive layer with UV light, the adhesive strength is reduced, and the adhered semiconductor chip can be easily removed.

When manufacturing a semiconductor device equipped with various types of semiconductor chips, only some of the semiconductor chips held by an adhesive tape may be used, and the remaining semiconductor chips may be processed separately. In this case, with direct bonding, if the time (Q-Time) after a surface activation treatment before semiconductor chip bonding becomes long, the effect of the surface activation treatment is lost, and the risk of bonding failure increases. Therefore, if a certain amount of time passes after the surface activation treatment for the semiconductor chips before direct bonding, it becomes necessary to perform the surface activation treatment again.

However, conventionally, a treatment for reducing the adhesive strength of an adhesive tape has been applied to the entire surface of the adhesive tape, making all of the semiconductor chips held by the adhesive tape easy to remove. Therefore, when the semiconductor chip was subjected to another surface activation treatment, there was a risk that the semiconductor chip might become misaligned or fall off.

### BRIEF SUMMARY

The UV light irradiation apparatus according to an embodiment of the present disclosure is a UV light irradiation apparatus for irradiating UV light onto a resin film having multiple electronic components adhered to a first surface of the resin film. The UV light irradiation apparatus includes a support stage for supporting the resin film; a light source portion irradiating UV light onto a second surface of the resin film opposite the first surface; and a mask portion disposed between the resin film and the light source portion and shielding a part of the UV light.

The UV light irradiation apparatus according to an embodiment of the present disclosure is a UV light irradiation apparatus for irradiating UV light onto a resin film having multiple electronic components adhered to a first surface of the resin film. The UV light irradiation apparatus includes a support stage for supporting the resin film; and a light source portion selectively irradiating UV light onto a desired area of a second surface opposite the first surface of the resin film.

### BRIEF DESCRIPTION OF THE SEVERAL VIEWS OF THE DRAWINGS

FIG. 1 is a block diagram showing an overall configuration of a mounting system according to an embodiment of the present disclosure.

FIG. 2A is a plan view showing a configuration of a supply substrate, which is a treatment target of a mounting system according to an embodiment of the present disclosure.

FIG. 2B is a plan view showing a configuration of a supply substrate, which is a treatment target of a mounting system according to an embodiment of the present disclosure.

FIG. 2C is a plan view showing a configuration of an adhesive tape, which is a treatment target of a mounting system according to an embodiment of the present disclosure.

FIG. 3A is a schematic cross-sectional view showing a configuration of a UV light irradiation unit according to an embodiment of the present disclosure.

FIG. 3B is a plan view showing a configuration of a mask unit in a UV light irradiation unit according to a modification of an embodiment of the present disclosure.

FIG. 3C is a plan view showing a configuration of a mask unit according to a modification of an embodiment of the present disclosure.

FIG. 3D is a plan view showing a configuration of a mask unit according to a modification of an embodiment of the present disclosure.

FIG. 3E is a cross-sectional view showing a configuration of a mask unit according to a modification of an embodiment of the present disclosure.

FIG. 3F is a diagram illustrating a case where an opening region is set to 0% using a mask unit according to a modification of an embodiment of the present disclosure.

FIG. 3G is a cross-sectional view showing a configuration of a mask unit according to a modification of an embodiment of the present disclosure.

FIG. 3H is a diagram illustrating a case where an opening region is set to 25% using a mask unit according to a modification of an embodiment of the present disclosure.

FIG. 3I is a cross-sectional view showing a configuration of a mask unit according to a modification of an embodiment of the present disclosure.

FIG. 3J is a diagram illustrating a case where the position and/or area of an opening region is changed using a mask unit according to a modification of an embodiment of the present disclosure.

FIG. 4A is a schematic cross-sectional view showing a configuration of a UV light irradiation unit according to an embodiment of the present disclosure.

FIG. 4B is a plan view showing a configuration of a mask unit according to an embodiment of the present disclosure.

FIG. 5A is a schematic cross-sectional view showing a configuration of a UV light irradiation unit according to an embodiment of the present disclosure.

FIG. 5B is a plan view showing a configuration of a light source unit according to an embodiment of the present disclosure.

FIG. 6A is a schematic cross-sectional view showing a configuration of a UV light irradiation unit according to an embodiment of the present disclosure.

FIG. 6B is a plan view showing a configuration of a light source unit according to an embodiment of the present disclosure.

FIG. 7A is a plan view showing a configuration of a light source unit according to a modification of an embodiment of the present disclosure.

FIG. 7B is a plan view showing a configuration of a light source unit according to a modification of an embodiment of the present disclosure.

FIG. 8 is a block diagram showing an overall configuration of a mounting system according to an embodiment of the present disclosure.

### DETAILED DESCRIPTION

Hereinafter, a UV light irradiation apparatus according to an embodiment of the present disclosure will be described with reference to the drawings. However, the UV light irradiation apparatus to which the present disclosure is applied can be implemented in many different forms and is not limited to the examples described below.

In the specification and claims of the present disclosure, “up” indicates a direction vertically away from an installation surface of the UV light irradiation apparatus (for example, a floor of a factory) in a state in which the UV light irradiation apparatus is installed for normal use, and “down” indicates a direction opposite to “up” (usually the direction of gravity). “Inside” indicates a direction toward the center of the UV light irradiation apparatus, and “outside” indicates a direction opposite to “inside”. In addition, “up-down direction” is synonymous with “vertical direction,” and “left-right direction” is synonymous with “horizontal direction.”

### First Embodiment

### Configuration of Mounting System 1

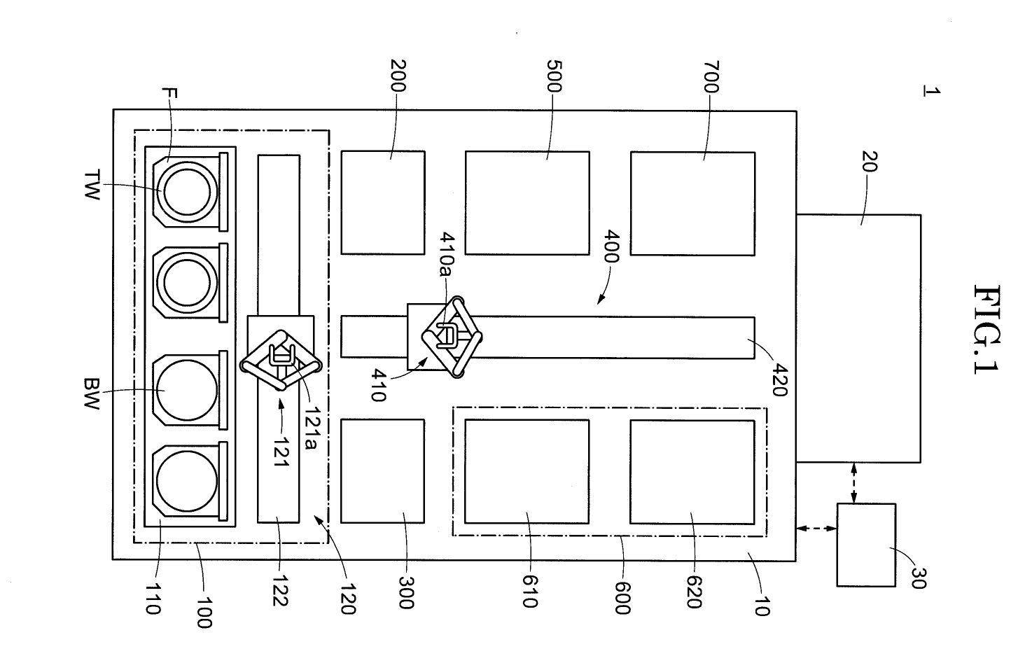

FIG. 1 is a block diagram showing an overall configuration of a mounting system 1 according to an embodiment of the present disclosure. For example, the mounting system 1 is an apparatus arranged in a factory for manufacturing a semiconductor integrated circuit and is used to mount electronic components, such as a semiconductor chip, on a substrate (mounting substrate) such as a semiconductor wafer. Specifically, the mounting system 1 of the present embodiment is a C2W (Chip to Wafer) mounting system that uses direct bonding technology to mount the semiconductor chip on the semiconductor wafer. In addition, the semiconductor wafer as the mounting substrate may be, for example, an interposer substrate with through electrodes formed in the semiconductor wafer, a circuit substrate with integrated circuits formed in the semiconductor wafer by a semiconductor process, or a circuit substrate with a plurality of semiconductor chips mounted on the semiconductor wafer.

In FIG. 1, when direct bonding is performed, a pretreatment apparatus 10 performs a surface activation treatment and a cleaning treatment on the bonding surfaces of the mounting substrates, such as the semiconductor chip and the semiconductor wafer. In addition, the pretreatment apparatus 10 performs pretreatment for mounting, such as UV light irradiation treatment, which irradiates the adhesive tape with UV light to reduce or eliminate the adhesive strength, so that the semiconductor chip can be easily picked up from the adhesive tape that supports the semiconductor chip. A bonding apparatus 20 mounts (places, loads, or temporarily bonds) the semiconductor chip that has been pretreated by the pretreatment apparatus 10 onto the mounting substrate that has also been pretreated. In addition, when direct bonding is not performed, the bonding apparatus 20 mounts (places, loads, or temporarily bonds) chips that have not been pretreated by the pretreatment apparatus onto the mounting substrate that has not been pretreated.

The mounting system 1 of the present embodiment includes the pretreatment apparatus 10 and the bonding apparatus 20 that mounts the electronic components received from the pretreatment apparatus 10 onto the substrate. The pretreatment apparatus 10 and the bonding apparatus 20 are controlled by a control unit 30 that is communicatively connected to the pretreatment apparatus 10 and the bonding apparatus 20. Therefore, strictly speaking, the mounting system 1 of the present embodiment includes the pretreatment apparatus 10, the bonding apparatus 20, and the control unit 30.

The pretreatment apparatus 10 is an apparatus for performing a pretreatment for direct bonding, such as an activation treatment and cleaning treatment of the bonding surface, and a treatment to reduce the adhesive strength of the adhesive tapes (UV light irradiation treatment) on a supply substrate TW and a mounting substrate BW, which are the treatment targets. The specific configuration of the pretreatment apparatus 10 will be described later.

The supply substrate TW is a substrate that enables the mounting system 1 to process the electronic components (semiconductor chips) to be mounted on the mounting substrate BW (the semiconductor wafer). Specifically, the supply substrate TW is a substrate having a structure in which a plurality of singulated semiconductor chips is attached (adhered) to the adhesive tape supported by a frame.

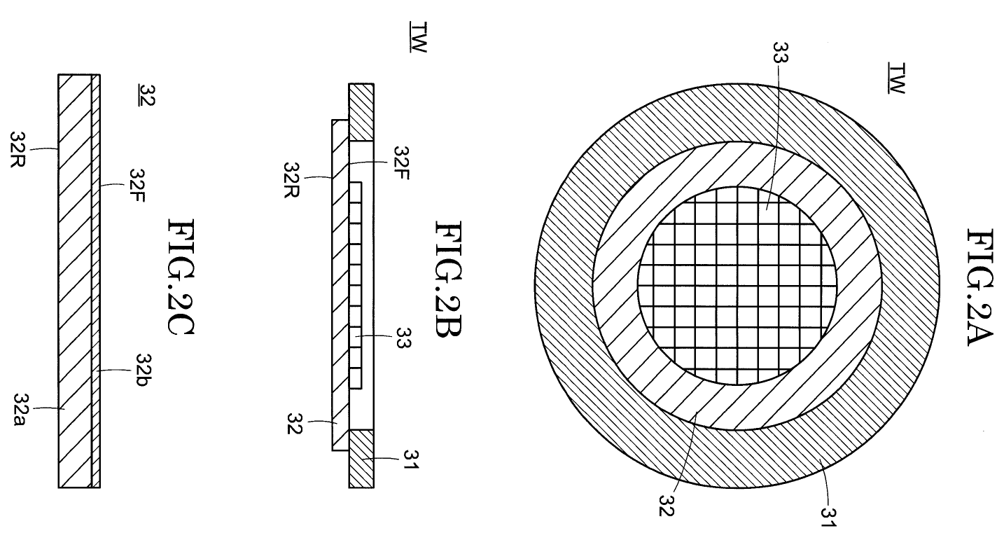

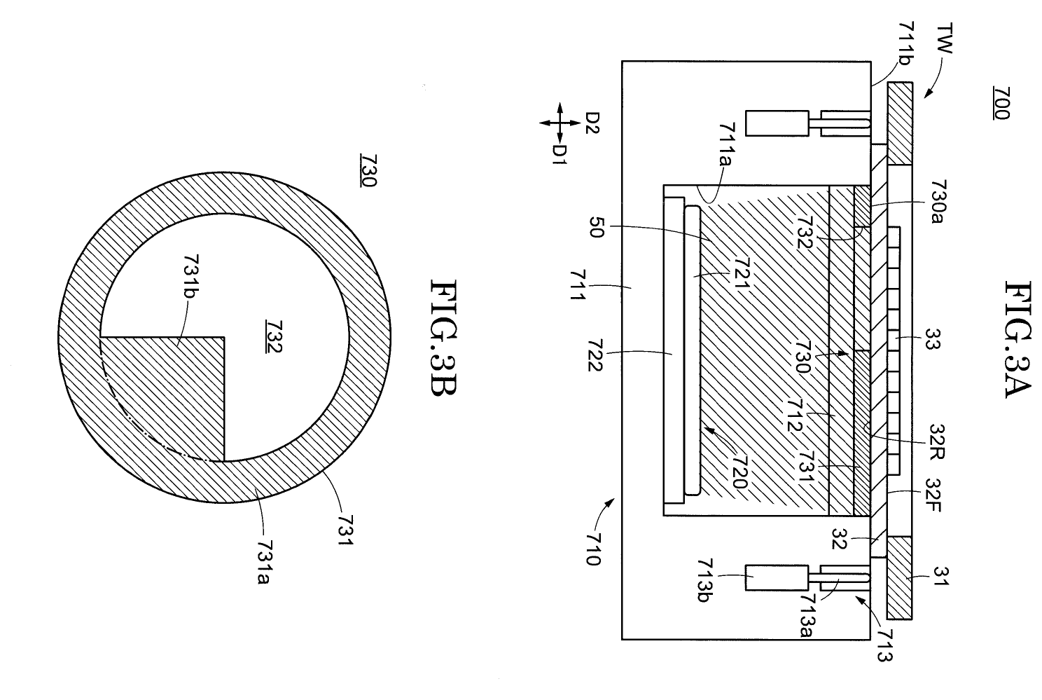

FIGS. 2A and 2B are diagrams showing configurations of the supply substrate TW, which is the treatment target of the mounting system 1 according to an embodiment of the present disclosure. FIG. 2A is a plan view of the supply substrate TW, and FIG. 2B is a cross-sectional view of the supply substrate TW seen from the side. As shown in FIG. 2A, the supply substrate TW includes a frame 31, an adhesive tape 32 supported by the frame 31, and a plurality of semiconductor chips 33 adhered to the adhesive tape 32.

The frame 31 is an annular frame made of stainless steel or the like, and is called a dicing frame, a tape frame, or the like. As shown in FIGS. 2A and 2B, the adhesive tape 32 has its outer edge attached to the frame 31 and is supported to cover an opening of the frame 31. The plurality of semiconductor chips 33 is attached to a surface (first surface 32F) of the adhesive tape 32. The plurality of semiconductor chips 33 is formed by singulating the semiconductor wafer (the semiconductor wafer with integrated circuits formed) attached to the adhesive tape 32. Furthermore, in the following description, the back surface of the adhesive tape (the surface opposite to the first surface 32F) is referred to as a second surface 32R.

FIG. 2C is a diagram showing a configuration of the adhesive tape 32 of the supply substrate TW, which is the treatment target of the mounting system 1 according to an embodiment of the present disclosure. The adhesive tape 32 is an adhesive tape formed by stacking resin layers. Specifically, the adhesive tape 32 is formed by stacking a first resin layer 32a as a base material and a second resin layer 32b as an adhesive layer. The adhesive tape 32 is attached to the frame 31 by the adhesiveness of the surface of the second resin layer 32b. That is, the plurality of semiconductor chips 33 is adhered to the surface of the second resin layer 32b (corresponding to the first surface 32F). The UV light irradiation apparatus described later irradiates the second resin layer 32b with UV light to cure the second resin layer 32b and reduce the adhesiveness. That is, the second resin layer 32b is composed of the UV-curable resin. The first resin layer 32a is composed of a resin that transmits UV light, and the UV light is irradiated onto the back surface (corresponding to the second surface 32R) of the first resin layer 32a. That is, the second resin layer 32b is cured by being irradiated with the UV light that has passed through the first resin layer 32a.

Returning to the explanation of FIG. 1, the bonding apparatus 20 is an apparatus that mounts the semiconductor chip, whose bonding surface has been activated by the pretreatment apparatus 10, onto the mounting substrate BW. The mounting system 1 includes the pretreatment apparatus 10 and the bonding apparatus 20. Since the pretreatment apparatus 10 and the bonding apparatus 20 are arranged adjacent to each other, the supply substrate TW and the mounting substrate BW, whose bonding surfaces have been activated by the pretreatment apparatus 10, can be transferred continuously to the bonding apparatus 20 without delay. Therefore, direct bonding can be performed before the active states of the bonding surfaces of the semiconductor chip and the semiconductor wafer deteriorate, and a decrease in strength during bonding can be prevented. In addition, the mounting system 1 may integrate the pretreatment apparatus 10 and the bonding apparatus 20.

The control unit 30 controls the pretreatment apparatus 10 and the bonding apparatus 20. The control unit 30 includes a storage unit and a processor. The storage unit stores a control program for controlling the operations of the pretreatment apparatus 10 and the bonding apparatus 20, as well as various control data for executing the control program. The processor controls the pretreatment apparatus 10 and the bonding apparatus 20 by reading and executing the control program described above from the storage unit. The control unit 30 may include a display device, such as a touch panel, as a user interface for receiving an input from an operator controlling the mounting system 1.

### Configuration of Pretreatment Apparatus 10

The pretreatment apparatus 10 includes a load/unload unit 100, a supply buffer unit 200, a discharge buffer unit 300, a workpiece transport unit 400, an activation processing unit 500, a cleaning unit 600, and a UV light irradiation unit 700. However, the configuration of the pretreatment apparatus 10 is not limited to this example, and some components shown in FIG. 1 may be omitted, or other components may be added.

The load/unload unit 100 handles the transportation of a workpiece such as the supply substrate TW and the mounting substrate BW between the mounting system 1 and the outside. The workpiece received from outside the mounting system 1 before mounting process is temporarily held in the supply buffer unit 200. In addition, the workpiece to be discharged to the outside of the mounting system 1 after the mounting process is held in the discharge buffer unit 300. The supply substrate TW and the mounting substrate BW supplied into the mounting system 1 before the mounting process are subjected to an activation process of the bonding surfaces in the activation processing unit 500. The workpiece after the activation process is cleaned in the cleaning unit 600. The UV light irradiation unit 700 irradiates UV light onto the cleaned supply substrate TW, reducing the adhesive strength of the adhesive tape, on which the electronic components such as semiconductor chips are mounted. The workpiece transport unit 400 transports the workpiece to each processing unit such as the activation processing unit 500 and the UV light irradiation unit 700.

The load/unload unit 100 is an apparatus for transporting the workpiece, such as the supply substrate TW and the mounting substrate BW, and includes a container installation unit 110 and a workpiece transport unit 120. In the present embodiment, a so-called EFEM (Equipment Front End Module) is used as the load/unload unit 100.

The container installation unit 110 is a platform for installing a workpiece transport container F called a FOUP (Front-Opening Unified Pod). The workpiece transport container F accommodates workpieces (the supply substrate TW and the mounting substrate BW) supplied to the pretreatment apparatus 10, or workpieces (mounted substrates) discharged from the pretreatment apparatus 10. In the example shown in FIG. 1, four workpiece transport containers F are lined up in the container installation unit 110. Specifically, the two workpiece transport containers F on the left side accommodate the supply substrate TW, and the two on the right side accommodate the mounting substrate BW. After being used in the mounting process, the supply substrate TW is returned to an empty slot in the workpiece transport container F that accommodates the supply substrate TW before the mounting process. Similarly, the mounted substrate BW after the mounting process is returned to an empty slot in the workpiece transport container F that accommodates the mounting substrate BW before the mounting process.

The workpiece transport unit 120 includes a transport robot 121 and a moving mechanism 122. The transport robot 121 is a robot that handles workpieces and transports workpieces using a transport arm 121a. The moving mechanism 122 is a mechanism for moving the transport robot 121 and positioning the transport robot 121. Specifically, the moving mechanism 122 adjusts the position of the transport robot 121 to match the position of the workpiece transport container F installed in the container installation unit 110, the supply buffer unit 200, and the discharge buffer unit 300, which will be described later.

The supply buffer unit 200 is a unit for temporarily holding the workpieces before the mounting process. For example, the supply buffer unit 200 can temporarily hold the workpieces (the supply substrate TW and the mounting substrate BW) supplied to the pretreatment apparatus 10 by the load/unload unit 100 until the workpieces are transported by the workpiece transport unit 400 described later. The supply buffer unit 200 may be configured to hold a plurality of workpieces.

The discharge buffer unit 300 is a unit for temporarily holding the workpieces after the mounting process. Specifically, the workpieces (mounted substrates) on which the semiconductor chip has been mounted by the bonding apparatus 20 are temporarily held. For example, the discharge buffer unit 300 can temporarily hold the workpieces discharged from the bonding apparatus 20 until the workpieces are transported by the workpiece transport unit 120 of the load/unload unit 100. The discharge buffer unit 300 may be configured to hold a plurality of workpieces.

The workpiece transport unit 400 is an apparatus for transporting workpieces to each processing unit such as the activation processing unit 500 and the UV light irradiation unit 700, and includes a transport robot 410 and a moving mechanism 420. The transport robot 410 is a robot that handles workpieces and transports workpieces using a transport arm 410a. The moving mechanism 420 is a mechanism for moving the transport robot 410 and positioning the transport robot 410. Specifically, the moving mechanism 420 adjusts the position of the transport robot 410 to match the position of each processing unit.

The activation processing unit 500 is an apparatus (plasma treatment device) for performing processing to activate the bonding surfaces of the semiconductor chips included in the supply substrate TW. Specifically, the activation processing unit 500 performs a plasma treatment on the bonding surfaces of the semiconductor chips. In the present embodiment, nitrogen gas is used as the gas used in the plasma treatment. However, the present disclosure is not limited to this example, and an inert gas other than nitrogen gas (for example, argon gas, helium gas, neon gas) may be used as the gas used in the plasma treatment. In addition, the gas used in the plasma treatment is not limited to an inert gas, and oxygen gas, hydrogen gas, or water vapor may also be used. By using these gases, cleaning to remove organic substances from the bonding surfaces can be performed, and activation to remove oxide films formed on the bonding surfaces and terminate the insulating films on the bonding surfaces with hydroxyl groups can be performed. In particular, it is preferable to include water vapor during the plasma treatment, as it allows for efficient termination of the insulating film on the bonding surfaces with hydroxyl groups. In addition, the activation processing unit 500 performs an activation process not only on the bonding surfaces of the semiconductor chips in the supply substrate TW but also on the bonding surfaces of the mounting substrate BW (for example, semiconductor wafer).

The cleaning unit 600 is an apparatus (cleaning apparatus) for cleaning workpieces. In the present embodiment, the cleaning unit 600 includes a supply-substrate cleaning unit 610 and a mounting-substrate cleaning unit 620. The supply-substrate cleaning unit 610 is an apparatus for cleaning the supply substrate TW, and the mounting-substrate cleaning unit 620 is an apparatus for cleaning the mounting substrate BW. Since the supply substrate TW and the mounting substrate BW may have different sizes (diameters), the throughput can be improved by providing dedicated devices for each. However, the present disclosure is not limited to this example, and a configuration may be adopted in which one cleaning apparatus handles both the cleaning of the supply substrate TW and the mounting substrate BW.

The supply-substrate cleaning unit 610 and the mounting-substrate cleaning unit 620 are composed of cleaning apparatuses that perform spin cleaning of workpieces. In the present embodiment, after the plasma treatment is performed on the supply substrate TW and the mounting substrate BW in the activation processing unit 500, the supply substrate TW and the mounting substrate BW are cleaned in the supply-substrate cleaning unit 610 and the mounting-substrate cleaning unit 620, respectively. As a result, the bonding surfaces of the semiconductor chip and the semiconductor wafer are efficiently terminated with hydroxyl groups, making them suitable for direct bonding.

The UV light irradiation unit 700 is an apparatus (the UV light irradiation apparatus) for irradiating UV light onto the supply substrate TW. The UV light irradiation unit 700 has a function of reducing the adhesive strength of the adhesive tape by irradiating UV light onto the adhesive tape to which the semiconductor chip is adhered to the supply substrate TW. This makes it easier to remove the semiconductor chip from the adhesive tape when picking it up from the supply substrate TW in the bonding apparatus 20. Details of the UV light irradiation unit 700 will be described below.

### Configuration of UV Light Irradiation Unit 700

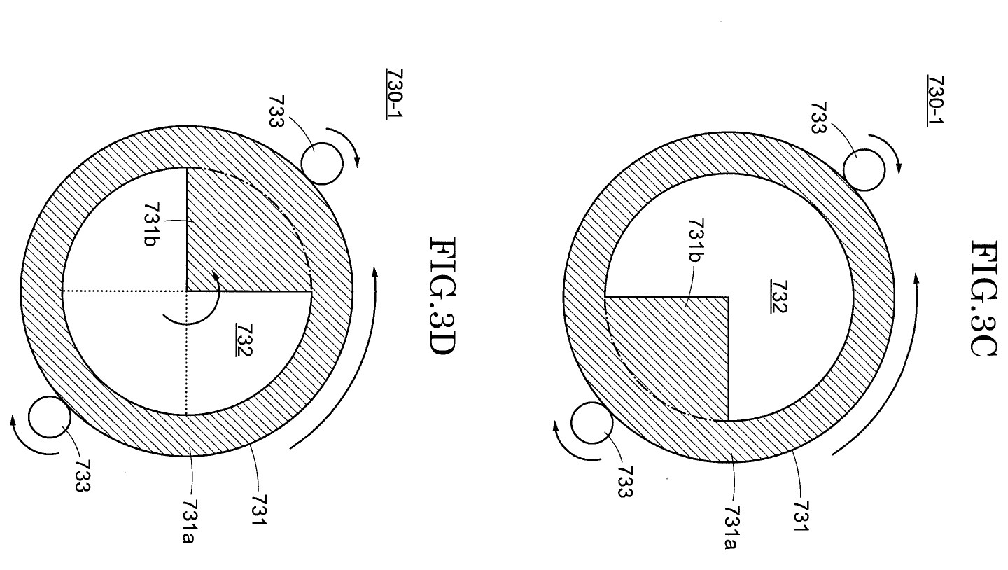

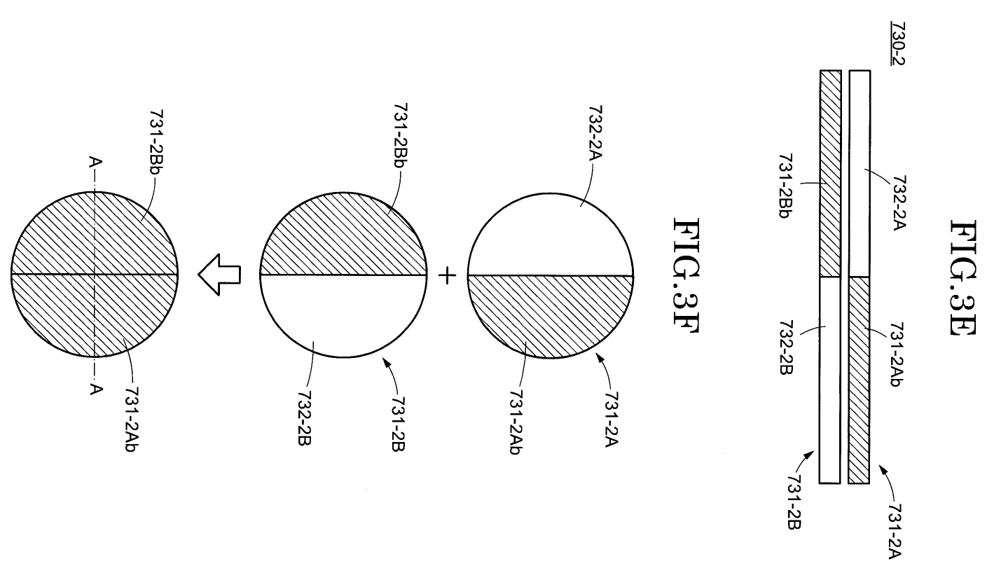

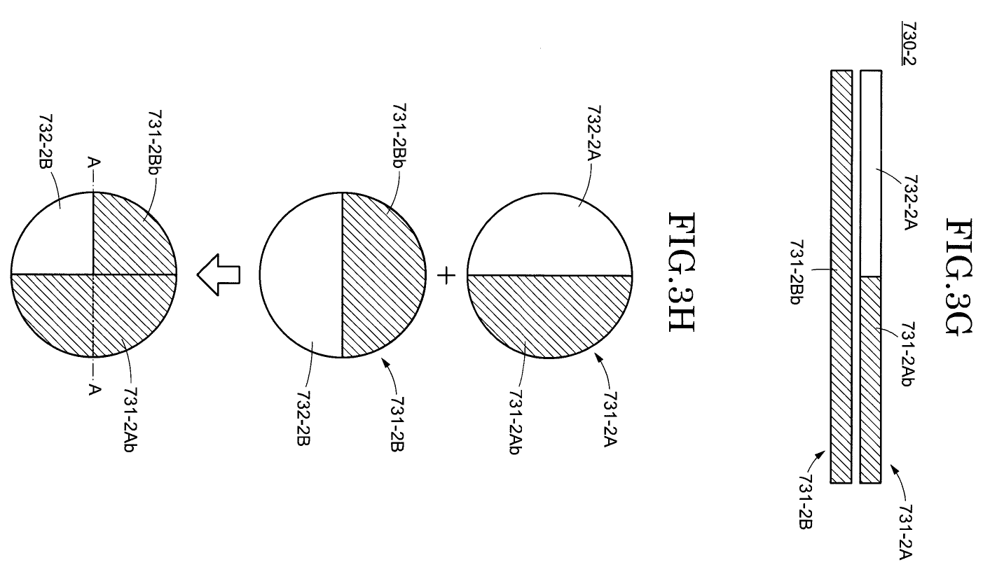

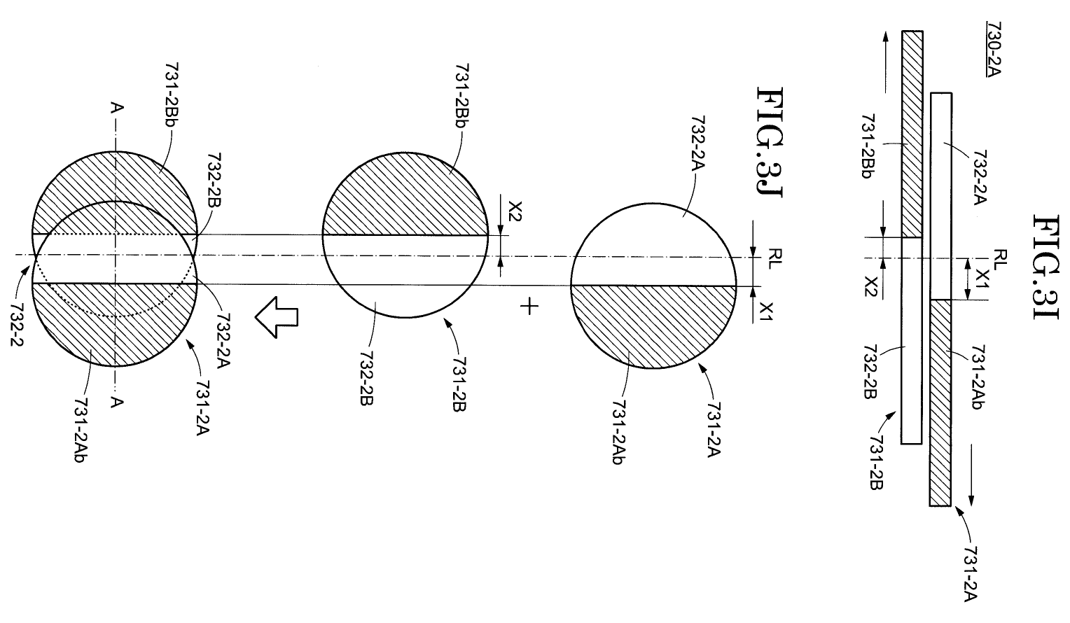

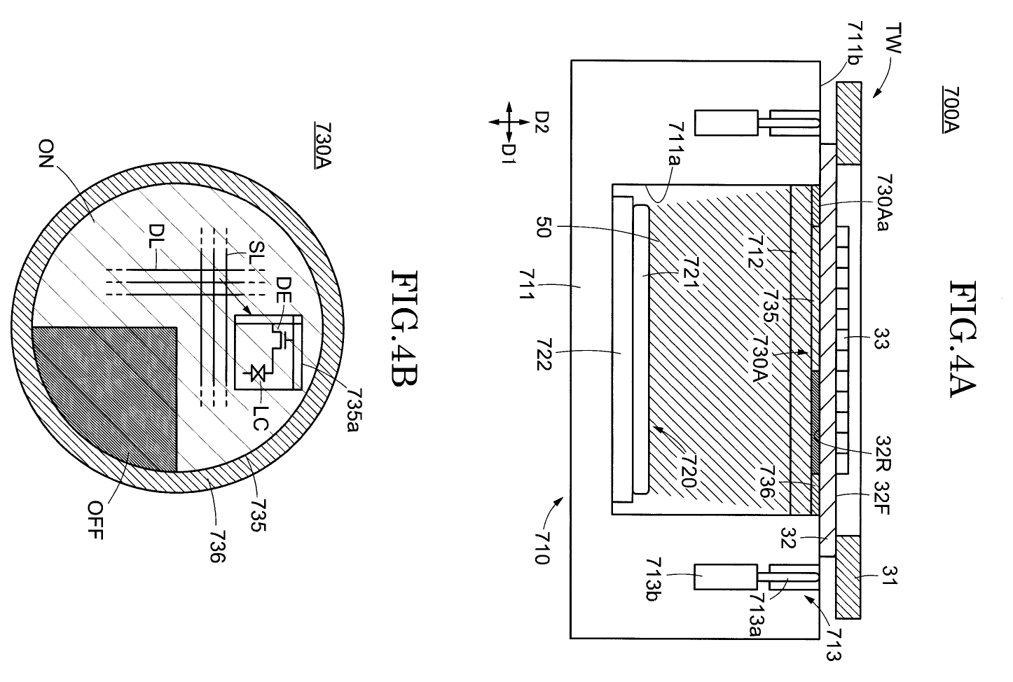

FIG. 3A is a schematic cross-sectional view showing a configuration of the UV light irradiation unit 700 according to an embodiment of the present disclosure. The UV light irradiation unit 700 is the UV light irradiation apparatus for irradiating UV light onto the resin film (the adhesive tape 32) to which a plurality of electronic components (the semiconductor chip 33) is adhered to the first surface (front surface). As shown in FIG. 3A, the UV light irradiation unit 700 includes a support stage 710, a light source unit 720, and a mask unit 730. However, the configuration of the UV light irradiation unit 700 is not limited to this example, and some components shown in FIG. 3A may be omitted, or other components may be added. Furthermore, in FIG. 3 and subsequent figures, a direction D1 indicates the left-right direction (horizontal direction), and a direction D2 indicates the up-down direction (vertical direction).

The support stage 710 includes a housing 711, a light-transmitting member 712, and a plurality of push-pull mechanisms 713. However, the configuration of the support stage 710 is not limited to this example, and some components shown in FIG. 3A may be omitted, or other components may be added. The housing 711 is a member that serves as the base of the support stage 710 and functions as a pedestal to support the supply substrate TW.

The housing 711 has an opening 711a at its center, and the light-transmitting member 712 that transmits UV light is arranged inside the opening 711a. As shown in FIG. 3A, the opening 711a is provided to face the supply substrate TW placed on the housing 711. Although not shown, in the present embodiment, the outer shape of the opening 711a is made annular according to the annular outer shape of the frame 31 of the supply substrate TW (see FIG. 2A). In addition, the opening 711a is intended to ensure an optical path for UV light irradiated onto the supply substrate TW (specifically, the adhesive tape 32), and is not particularly limited to the annular outer shape.

A quartz member or a glass member can be used as the light-transmitting member 712. In the present embodiment, an annular light-transmitting member 712 is fitted inside the upper end of opening 711a, but the present disclosure is not limited to this example. For example, a rectangular light-transmitting member 712 may be provided to cover the annular opening 711a. For example, if the supply substrate TW can be supported by supporting the frame 31, the light-transmitting member 712 may be omitted.

Each push-pull mechanism 713 includes a support pin 713a and a pin drive unit 713b that moves the support pin 713a in the up-down direction, and is arranged around the opening 711a. As shown in FIG. 3A, the push-pull mechanism 713 has a function of supporting the supply substrate TW when the supply substrate TW is placed on the support stage 710. Therefore, although not shown, in the present embodiment, four push-pull mechanisms 713 are arranged around the opening 711a at positions symmetrical to the center of the opening 711a. However, the arrangement of the push-pull mechanism 713 is not limited to this example, and the push-pull mechanism 713 may be arranged in any manner as long as it is able to support the supply substrate TW.

The light source unit 720 is arranged below the light-transmitting member 712 and has a function of irradiating UV light upward. The light source unit 720 includes a light source 721 and a light source drive portion 722 that drives the light source 721. In the present embodiment, the light source 721 is a circular surface light source in which a plurality of light-emitting diodes (LEDs) that emit UV light is arranged. However, the present disclosure is not limited to this example, and a UV lamp that emits UV light may be used as the light source 721. In addition, the light source 721 is not limited to a circular shape and may be polygonal, such as a rectangle. The light source drive portion 722 may include a power supply circuit and a driving circuit for causing the light source 721 to emit light.

In the present embodiment, the surface light source is used as the light source 721, and a configuration is adopted in which UV light can be irradiated onto the adhesive tape 32 of the supply substrate TW at once, but the present disclosure is not limited to this example. For example, a linear light source may be used as the light source 721, and by scanning the light source 721 in one direction, UV light can be irradiated from one end to the other end of the adhesive tape 32 of the supply substrate TW. In this case, the light source drive portion 722 may include a moving mechanism (for example, an actuator) for scanning the light source 721, in addition to the power supply circuit and the driving circuit described above.

Although not shown, the light source unit 720 may have an optical system for changing the irradiation direction of UV light or processing the shape of UV light. For example, in the example shown in FIG. 3A, although the configuration in which the light source 721 is arranged below the light-transmitting member 712 is exemplified, the present disclosure is not limited to this example, and the light source 721 may be arranged at a position other than below the light-transmitting member 712, and UV light may be guided to the light-transmitting member 712 using the optical system. In addition, when the light source 721 is scanned to irradiate UV light, an optical system may be provided to process the shape of the UV light emitted from the light source 721, which is configured by the linear light source, into a rectangular shape or other shape.

The mask unit 730 has a function of shielding a part of the UV light emitted from the light source unit 720. Specifically, the mask unit 730 has a function of shielding a part of the UV light irradiated upward from the light source 721 and preventing the light from reaching the adhesive tape 32. As shown in FIG. 3A, in the present embodiment, the mask unit 730 is composed of a member with an opening 732 on a mask body 731. In the example shown in FIG. 3A, the opening 732 is provided only in a region of the adhesive tape 32 overlapping a portion of the semiconductor chip 33. Therefore, the UV light reaches only the region of the adhesive tape 32 overlapping the opening 732. Hereinafter, a region of the adhesive tape 32 overlapping the mask body 731 in a plan view is referred to as a “mask region”.

The mask unit 730 in the present embodiment is arranged inside the opening 711a of the housing 711 and above the light-transmitting member 712. Specifically, the mask unit 730 is arranged between the light-transmitting member 712 and the adhesive tape 32 of the supply substrate TW. In addition, although a case where the mask unit 730 is in contact with the adhesive tape 32 of the supply substrate TW will be described in the present embodiment, a light-transmitting member other than the light-transmitting member 712 may be arranged between the mask unit 730 and the adhesive tape 32.

In the structure shown in FIG. 3A, since the supply substrate TW is placed directly above the mask unit 730, it is desirable to configure an upper surface 711b of the housing 711 of the support stage 710 and an upper surface 730a of the mask unit 730 to form a flat surface that supports the supply substrate TW. In addition, with this structure, since the mask unit 730 and the adhesive tape 32 of the supply substrate TW are in contact with (or close to) each other, interference of UV light can be suppressed, and the range of the mask region can be accurately controlled. However, the present disclosure is not limited to this example, and the positional relationship between the light-transmitting member 712 and the mask unit 730 may be reversed. That is, the mask unit 730 may be provided below the light-transmitting member 712, and only the UV light that passes through the opening 732 may pass through the light-transmitting member 712 and be irradiated onto the adhesive tape 32.

FIG. 3B is a plan view showing a configuration of the mask unit 730 in the UV light irradiation unit 700 according to an embodiment of the present disclosure. As shown in FIG. 3B, the mask body 731 in the present embodiment is a circular outer-shaped member, and is composed of a material capable of shielding UV light. For example, the mask body 731 is composed of a metal member, a ceramic member, a plastic member that is light-shielding to UV light, or the like. In the example shown in FIG. 3B, the mask body 731 includes an annular-shaped first light-shielding portion 731a and a folding fan-shaped second light-shielding portion 731b having a concentric outer shape with a diameter smaller than the outer shape of the mask body 731 and occupying one-quarter of a circular region. However, the present disclosure is not limited to this example, and the area of the region occupied by the second light-shielding portion 731b is arbitrary.

The opening 732 is a portion of the mask unit 730 that forms an optical path through which UV light passes, and is a closed region surrounded by the mask body 731. In the present embodiment, the opening 732 is a region other than one-quarter of the circular region (the region occupied by the second light-shielding portion 731b) having a concentric outer shape with a diameter smaller than the outer shape of the mask body 731. That is, the opening 732 occupies three-quarters of the circular region described above.

The first light-shielding portion 731a shields a region outside the semiconductor chip 33 assembly (that is, the singulated semiconductor wafer). Specifically, the first light-shielding portion 731a shields a region of the adhesive tape 32 shown in FIG. 3A not overlapping the semiconductor chip 33 and overlapping the inside of the opening 711a of the housing 711. The first light-shielding portion 731a supports the second light-shielding portion 731b, and also prevents UV light from being irradiated into the apparatus through the gap between the semiconductor chip 33 and the inner wall of the opening 711a.

The UV light irradiation unit 700 in the present embodiment can selectively (partially) irradiate UV light using the mask unit 730 onto three-quarters of the region (a region overlapping the opening 732) in the adhesive tape 32 where the semiconductor chip 33 is adhered (circular region shown in FIG. 2A). In the present embodiment, by appropriately setting the position of the region where the mask body 731 and the adhesive tape 32 overlap (mask region, that is, the second light-shielding portion 731b) when arranging the mask portion 730, it is possible to selectively set the region of the adhesive tape 32 where the adhesive strength is reduced (region where UV light is irradiated).

As described above, the UV light irradiation unit 700 in the present embodiment can shield a part of the UV light emitted from the light source unit 720 using the mask unit 730, and selectively irradiate the UV light onto the adhesive tape 32 of the supply substrate TW. That is, the UV light irradiation unit 700 in the present embodiment can selectively irradiate the UV light onto the second surface 32R of the adhesive tape 32 by using the light source unit 720 and the mask unit 730 in cooperation to limit the irradiation region.

According to the present embodiment, the UV light is selectively irradiated only onto the region of the adhesive tape 32 that overlaps the opening 732, so that the adhesive strength can be reduced only in that region. That is, when UV light is irradiated onto the adhesive tape 32 to reduce the adhesive strength, the adhesive strength in a desired region can be selectively reduced. Conversely, the adhesive strength of the adhesive tape 32 in the mask region does not decrease even after the UV light irradiation, and the semiconductor chip 33 can be held. As a result, according to the present embodiment, unused semiconductor chips 33 on the supply substrate TW supplied to the bonding apparatus 20 can be subjected to the surface activation treatment and the cleaning treatment again. Therefore, according to the present embodiment, it becomes possible to bring back the supply substrate TW on which the semiconductor chips 33 that have not been used in the bonding apparatus 20 are mounted and reuse it as the supply substrate TW.

In addition, in order to make the role of the mask unit 730 explained above function effectively, it is desirable to accurately align the mask unit 730 with an assembly of semiconductor chips 33 (hereinafter referred to as a “semiconductor chip group”). When placing the supply substrate TW on the support stage 710, it is relatively easy to align the center position of the frame 31 with the center position of the mask unit 730. However, since the center position of the semiconductor wafer before singulation may not coincide with the center position of the frame 31, the center position of the semiconductor chip group and the frame 31 may be misaligned. In this case, simply aligning the center position of the frame 31 with the center position of the mask unit 730 may result in a misalignment between the center position of the semiconductor chip group and the mask unit 730, and there is a risk that the desired region may not be shielded with the mask unit 730.

To avoid such a situation, it is desirable to determine in advance the center position of the semiconductor chip group on the supply substrate TW and the rotation angle of the semiconductor chip group from a predetermined reference line, and when placing the supply substrate TW on the support stage 710, perform position correction based on the center position and rotation angle of the semiconductor chip group described above. The center position of the semiconductor chip group can be determined as the intersection of two line segments representing the maximum outer diameter of the semiconductor chip group. For example, the maximum outer diameter of the semiconductor chip group can be determined by analyzing a planar image of the semiconductor chip group acquired by an imaging device. The rotation angle of the semiconductor chip group can be obtained by analyzing the planar image described above, and as the angle formed by a predetermined reference line and any dicing line (a cutting line when the semiconductor wafer is singulated). However, the method for determining the center position and rotation angle of the semiconductor chip group is not limited to the examples described above.

By performing position correction of the supply substrate TW based on the center position and rotation angle of the semiconductor chip group describe above, the alignment between the mask unit 730 and the semiconductor chip group can be made more accurate, and the alignment accuracy of the region shielded by the mask unit 730 can be further improved.

### First Modification

Although the configuration in which one-quarter of the circular region where the semiconductor chip 33 is bonded to the adhesive tape 32 is covered with the mask body 731 is shown in the example shown in FIG. 3B, the present disclosure is not limited to this example. Regions with any desired area, such as one-half, three-quarters, one-eighth, or three-eighths of the circular region described above, can be covered with the mask body 731.

In addition, although a method for shielding a part of the adhesive tape 32 using a folding fan-shaped region as the unit is shown in the example shown in FIG. 3B, the present disclosure is not limited to this example. The shape and range of the region shielded from the UV light (that is, the shape and range of the opening 732 in the mask unit 730) can be set arbitrarily.

### Second Modification

In the examples shown in FIGS. 3A and 3B, the region where the opening 732 and the adhesive tape 32 overlap may be fixed or changeable. In the present modification, an example in which the position of the opening 732 of a mask unit 730-1 is made changeable will be described.

FIGS. 3C and 3D are plan views showing a configuration of the mask unit 730-1 according to a modification of an embodiment of the present disclosure. In the examples shown in FIGS. 3C and 3D, two rotational drive units 733 are provided around the mask body 731. Each rotational drive unit 733 is in contact with the mask body 731. As shown in FIGS. 3C and 3D, when each rotational drive unit 733 rotates clockwise, the mask body 731 rotates counterclockwise. As described above, in the present modification, the position of the mask region can be changed by controlling the rotation of the rotational drive unit 733. In the examples shown in FIGS. 3C and 3D, the position of the second light-shielding portion 731b (folding fan-shaped mask region) of the mask body 731 moves according to the rotation of the mask body 731. In the present modification, an example in which the mask body 731 is rotated 180 degrees from the state shown in FIG. 3C to the state shown in FIG. 3D is shown. In addition, the rotation direction of the rotational drive unit 733 does not need to be unidirectional and may be rotatable both clockwise and counterclockwise.

An assembly formed of the mask body 731 and the rotational drive unit 733 only needs to have a structure in which the rotational power of the rotational drive unit 733 is transmitted to the mask body 731. For example, a structure may be implemented in which a pulley or roller that engages with a groove or gear provided on the outer periphery of the mask body 731 may be installed on the side surface of opening 711a in the housing 711, the pulley or roller is rotated using a drive source (such as a servomotor), and the mask body 731 is rotated at a predetermined angle. In addition, a non-powered holding rotor that holds the mask body 731 rotatably may be provided at a predetermined position on the side surface of the opening 711a. Furthermore, although an example in which two rotational drive units 733 are arranged is shown in the example shown in FIG. 3C, the present disclosure is not limited to this example, and one or three or more rotational drive units 733 may be arranged.

### Third Modification

Although the example in which an opening region (region that transmits UV light) is formed in a desired region using a single mask unit 730 is shown in the examples shown in FIGS. 3A and 3B, it is also possible to form an opening region in the desired region using a plurality of mask units. In the present modification, an example in which an opening region is formed using two mask bodies (a first mask body 731-2A and a second mask body 731-2B) is described.

FIG. 3E is a cross-sectional view showing a configuration of the mask unit 730-2 according to the third modification of an embodiment of the present disclosure. FIG. 3F is a diagram illustrating a case where the opening region is set to 0% using the mask unit 730-2 according to the third modification of an embodiment of the present disclosure. The mask unit 730-2 includes the first mask body 731-2A and the second mask body 731-2B stacked in the up-down direction. An example in which the first mask body 731-2A is arranged above and the second mask body 731-2B is arranged below is shown here. In addition, FIG. 3E corresponds to a cross-sectional view obtained by cutting the bottom diagram in FIG. 3F along a line A-A.

For ease of explanation, the illustration of the annular light-shielding portion (the portion corresponding to the first light-shielding portion 731a in FIG. 3B) is omitted in the first mask body 731-2A and the second mask body 731-2B shown in FIGS. 3E and 3F. Although not shown, similar to the second modification described above, two rotational drive units are provided around each of the first mask body 731-2A and the second mask body 731-2B in the examples shown in FIGS. 3E and 3F. Therefore, the first mask body 731-2A and the second mask body 731-2B can be rotated independently using two rotational drive units, and the position of the shielded region (the region that does not transmit UV light) can be changed independently.

In the examples shown in FIGS. 3E and 3F, the first mask body 731-2A includes a light-shielding portion 731-2Ab and an opening 732-2A. The second mask body 731-2B includes a light-shielding portion 731-2Bb and an opening 732-2B. As shown in FIG. 3F, in the first mask body 731-2A, the light-shielding portion 731-2Ab occupies one-half of a circular region having a concentric outer shape with a diameter smaller than the outer shape of the first mask body 731-2A (not shown). The opening 732-2A occupies the region not shielded by the light-shielding portion 731-2Ab, that is, the remaining one-half of the circular region described above. Similar to the first mask body 731-2A, in the second mask body 731-2B, the light-shielding portion 731-2Bb occupies one-half of a circular region having a concentric outer shape with a diameter smaller than the outer shape of the second mask body 731-2B (not shown). The opening 732-2B occupies the region not shielded by the light-shielding portion 731-2Bb, that is, the remaining one-half of the circular region described above.

As shown in FIGS. 3E and 3F, the first mask body 731-2A shields the right half with the light-shielding portion 731-2Ab, and the second mask body 731-2B shields the left half with the light-shielding portion 731-2Bb. Therefore, as shown in the bottom diagram in FIG. 3F, the mask unit 730-2 is entirely composed of the shielding region, so that the opening region becomes 0%.

Next, an example in which the opening region is set to 25% using the first mask body 731-2A and the second mask body 731-2B described above will be described.

FIG. 3G is a cross-sectional view showing the configuration of the mask unit 730-2 according to the third modification of an embodiment of the present disclosure. FIG. 3H is a diagram illustrating a case where the opening region is set to 25% using the mask unit 730-2 according to the third modification of an embodiment of the present disclosure. FIG. 3G corresponds to a cross-sectional view obtained by cutting the bottom diagram in FIG. 3H along a line A-A.

As shown in FIGS. 3G and 3H, the first mask body 731-2A shields the right half with the light-shielding portion 731-2Ab, and the second mask body 731-2B shields the upper half with the light-shielding portion 731-2Bb. In this case, one-half of the region of the opening 732-2B of the second mask body 731-2B overlaps the light-shielding portion 731-2Ab of the first mask body 731-2A. Therefore, as shown in the bottom diagram in FIG. 3H, since only the lower left one-quarter of the mask unit 730-2 transmits UV light, the overall opening region is 25%.

As described above, according to the present modification, the position of the light-shielding region can be changed by independently rotating the first mask body 731-2A and the second mask body 731-2B, which are arranged to overlap in the up-down direction. That is, by controlling the rotation amount of each of the first mask body 731-2A and the second mask body 731-2B, it is possible to change the position and area of the opening region as the mask unit 730-2.

### Fourth Modification

Although the example in which the position and area of the opening region is changed by independently rotating the first mask body 731-2A and the second mask body 731-2B arranged to overlap in the up-down direction is shown in the third modification described above, an example in which the position and/or area of the opening region is changed by moving (sliding) the first mask body 731-2A and the second mask body 731-2B in the horizontal direction will be described in the present modification.

FIG. 3I is a cross-sectional view showing a configuration of a mask unit 730-2A according to the third modification of an embodiment of the present disclosure. FIG. 3J is a diagram illustrating a case of changing the position and/or area of the opening region using the mask unit 730-2A according to the third modification of an embodiment of the present disclosure. FIG. 3I corresponds to a cross-sectional view obtained by cutting the bottom diagram in FIG. 3J along a line A-A.

Similar to the third modification described above, the illustration of the annular light-shielding portion (corresponding to the first light-shielding portion 731a in FIG. 3B) is omitted in the first mask body 731-2A and the second mask body 731-2B shown in FIGS. 3I and 3J. Although not shown, in the examples shown in FIGS. 3I and 3J, movement drive units are provided to move the first mask body 731-2A and the second mask body 731-2B in the horizontal direction. Therefore, each of the first mask body 731-2A and the second mask body 731-2B can be independently moved using the movement drive units, so that the position of the light-shielding region can be changed independently.

In the example shown in FIG. 3I, the first mask body 731-2A is moved to the right by a distance X1 from a reference line RL. In addition, the second mask body 731-2B is moved to the left by a distance X2 from the reference line RL described above. In this case, the reference line RL corresponds to a centerline common to the first mask body 731-2A and the second mask body 731-2B in a state where the first mask body 731-2A and the second mask body 731-2B are not moving (a state in their initial positions). That is, the first mask body 731-2A moves to the right by the distance X1 from the reference line RL, and the light-shielding portion 731-2Ab moves to a position offset to the right by the distance X1 from the centerline. Similarly, the second mask body 731-2B moves to the left by the distance X2 from the reference line RL, and the light-shielding portion 731-2Bb moves to a position offset to the left by the distance X2 from the centerline.

Since the first mask body 731-2A and the second mask body 731-2B move as described above, the opening 732-2, composed by combining portions of the openings 732-2A and 732-2B, is formed between the light-shielding portions 731-2Ab and 731-2Bb. In this case, the portion of the opening 732-2A is a region with a width X1 adjacent to the light-shielding portion 731-2Ab, and the portion of the opening 732-2B is a region with a width X2 adjacent to the light-shielding portion 731-2Bb. Therefore, the opening 732-2 is a region of a width (X1+X2) formed between the light-shielding portion 731-2Ab and the light-shielding portion 731-2Bb.

As described above, according to the present modification, each of the first mask body 731-2A and the second mask body 731-2B, arranged to overlap in the up-down direction, can be moved independently to change the position of the light-shielding region. That is, by controlling the amount of movement of each of the first mask body 731-2A and the second mask body 731-2B, it is possible to change the position and area of the opening 732-2.

### Second Embodiment

In the present embodiment, an example in which the configuration of the mask unit is different from that of the first embodiment will be described. Specifically, a mask unit 730A of the present embodiment includes a liquid crystal shutter 735, and by controlling the on (light-transmitting state) /off (light-shielding state) of the liquid crystal shutter 735, a UV light 50 can be selectively irradiated onto the adhesive tape 32. A basic configuration of a UV light irradiation unit 700A of the present embodiment is similar to that of the UV light irradiation unit 700 of the first embodiment. Therefore, in the present embodiment, the explanation will focus on the parts of the configuration that are different from the first embodiment. For the same configuration as the UV light irradiation unit 700 of the first embodiment, redundant explanations may be omitted by using the same reference signs.

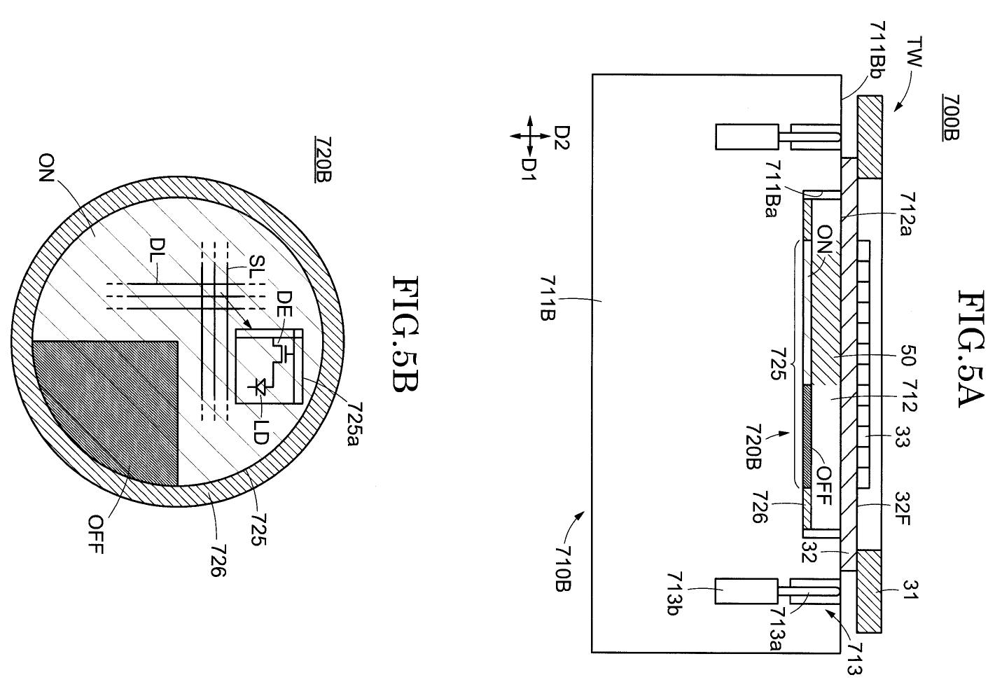

FIG. 4A is a schematic cross-sectional view showing a configuration of the UV light irradiation unit 700A according to an embodiment of the present disclosure. FIG. 4B is a plan view showing a configuration of the mask unit 730A according to an embodiment of the present disclosure. The mask unit 730A in the UV light irradiation unit 700A of the present embodiment includes the liquid crystal shutter 735. In the present embodiment, the mask unit 730A is arranged inside the opening 711a of the housing 711 and between the supply substrate TW and the light-transmitting member 712, similar to the mask unit 730 of the first embodiment. In addition, similar to the first embodiment, a flat surface for supporting the supply substrate TW is formed by the upper surface 711b of the housing 711 and an upper surface 730Aa of the mask unit 730A. However, the present disclosure is not limited to this example, and the positional relationship between the light-transmitting member 712 and the mask unit 730A may be reversed, or the light-transmitting member 712 may be omitted. In the case where the light-transmitting member 712 is omitted, the mask unit 730A functions as a support member of the supply substrate TW instead of the light-transmitting member 712.

As shown in FIGS. 4A and 4B, the mask unit 730A includes the liquid crystal shutter 735 and an outer frame 736 provided around the liquid crystal shutter 735. In the present embodiment, although an example in which the outer shape of the mask unit 730A is circular according to the shape of the light source unit 720 is shown, the present disclosure is not limited to this example and may be polygonal (for example, rectangular). That is, there are no particular limitations on the shapes of the light source unit 720 and the mask unit 730A. In addition, similar to the first embodiment, a linear light source may be used as the light source 721, and by scanning the light source 721 in one direction, UV light can be irradiated from one end to the other end of the adhesive tape 32 of the supply substrate TW.

As shown in FIG. 4B, the liquid crystal shutter 735 has a configuration in which a plurality of shutter regions 735a are arranged in a matrix on the substrate. A glass substrate, a quartz substrate, or a light-transmitting substrate such as a resin substrate with light transmittance can be used as the substrate. Each of the plurality of shutter regions 735a is a region surrounded by a scanning line SL and a data line DL, and includes a liquid crystal element LC and a driving element DE that controls the liquid crystal element LC. The liquid crystal shutter 735 functions as a mask that controls the transmission / non-transmission of the UV light 50.

The liquid crystal shutter 735 can switch the liquid crystal element LC to an on state (light-transmitting state) or an off state (light-shielding state) by controlling the driving element DE by supplying various signals to the scanning line SL and the data line DL. That is, when the liquid crystal element LC is in the on state, the shutter region 735a transmits the UV light 50, and when the liquid crystal element LC is in the off state, the shutter region 735a shields the UV light 50. As described above, by controlling the ON/OFF of each shutter region 735a, a light-transmitting region ON of the liquid crystal shutter 735 (a region functioning as an opening of the mask unit 730A) and a light-shielding region OFF (a region functioning as a mask region of the mask unit 730A) can be formed into a desired shape and range. Therefore, according to the present embodiment, by controlling the light-transmitting region ON and the light-shielding region OFF of the liquid crystal shutter 735, the UV light 50 can be selectively irradiated onto the desired region of the adhesive tape 32.

In addition, the liquid crystal shutter 735 can be divided into a plurality of blocks within the region, and the on/off can be controlled for each block. In this case, by adopting known local dimming to control the light source unit 720, it is possible to further clarify the distinction between the light-transmitting region ON and the light-shielding region OFF.

The outer frame 736 is a region surrounding the liquid crystal shutter 735, and is provided with wiring for supplying signals to the scanning line SL and the data line DL, and a driving circuit for generating or controlling those signals. The driving circuit arranged in the outer frame 736 may be formed on the substrate described above through a semiconductor process or may be mounted as a semiconductor chip.

In addition, the outer frame 736 of the present embodiment has a light-shielding property and functions as a mask region. For example, a light-shielding layer, such as a metal layer or a black resin layer, may be provided in a region corresponding to the outer frame 736 to give the outer frame 736 the function of shielding the transmission of the UV light 50. As shown in FIG. 4A, the outer frame 736 of the present embodiment overlaps a region of the adhesive tape 32 surrounding the semiconductor chip 33, preventing a decrease in adhesive strength in that region. In addition, the present disclosure is not limited to this example, and the light-shielding layer may not be provided in the outer frame 736, but since there is a risk that the elements forming the driving circuit will deteriorate if the driving circuit is exposed to the UV light 50, it is preferable to provide a light-shielding layer on the outer frame 736.

Furthermore, in the present embodiment, although a thin film transistor (TFT) is exemplified as the driving element DE, the present disclosure is not limited to this example, and other driving elements may be used. In addition, although an active matrix type liquid crystal shutter in which the driving element DE is arranged in each shutter region 735a is exemplified as the liquid crystal shutter 735, a simple matrix type liquid crystal shutter in which a liquid crystal layer is sandwiched between the scanning line SL and the data line DL may also be used.

### Third Embodiment

In the present embodiment, an example in which a configuration of the light source unit is different from that of the first embodiment will be described. Specifically, a light source unit 720B of the present embodiment includes an LED light source 725 including a plurality of light-emitting regions 725a, and by controlling the light emission (on/off control) of each light-emitting region 725a, the UV light 50 can be selectively irradiated onto the adhesive tape 32. A basic configuration of a UV light irradiation unit 700B of the present embodiment is similar to that of the UV light irradiation unit 700 of the first embodiment. Therefore, in the present embodiment, the explanation will focus on the parts of the configuration that are different from the first embodiment. For the same configuration as the UV light irradiation unit 700 of the first embodiment, redundant explanations may be omitted by using the same reference signs.

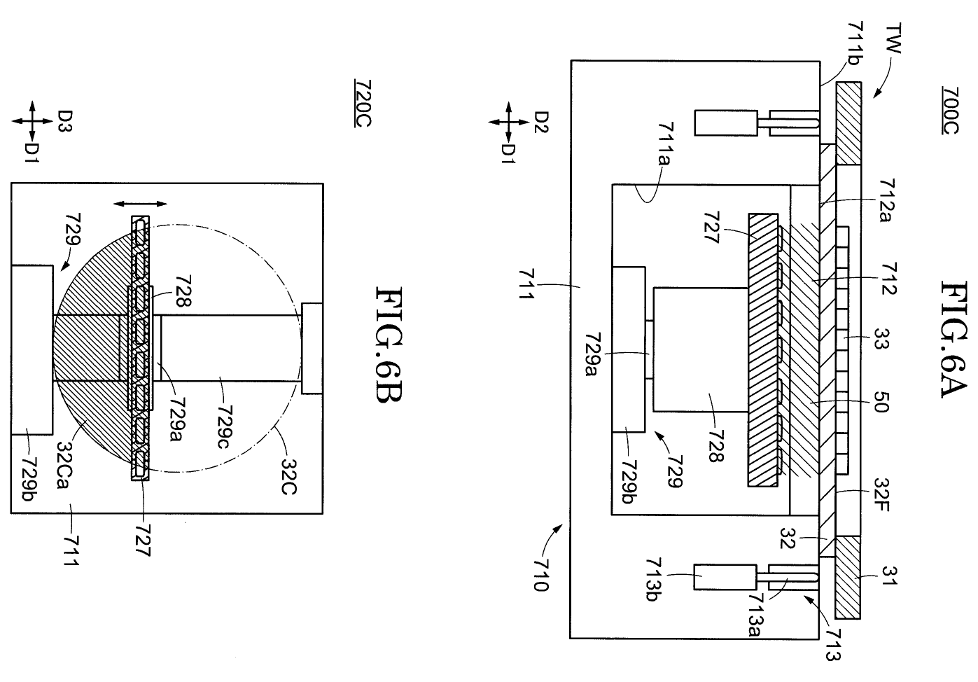

FIG. 5A is a schematic cross-sectional view showing a configuration of the UV light irradiation unit 700B according to an embodiment of the present disclosure. FIG. 5B is a plan view showing a configuration of the light source unit 720B according to an embodiment of the present disclosure. In the UV light irradiation unit 700B of the present embodiment, the light source unit 720B includes the LED light source 725 in which the plurality of light-emitting regions 725a is arranged in a matrix. As shown in FIG. 5A, in the present embodiment, the light source unit 720B is arranged directly below the light-transmitting member 712. In addition, a housing 711B of a support stage 710B has an opening 711Ba that is shallower than that of the first embodiment, and the light-transmitting member 712 and the light source unit 720B are housed inside the opening 711Ba. In the present embodiment, since a depth of the opening 711Ba is aligned with the total thickness of the light-transmitting member 712 and the light source unit 720B, an upper surface 712a of the light-transmitting member 712 and an upper surface 711Bb of the housing 711B form a flat surface. The shorter the distance between the light source unit 720B and the adhesive tape 32 of the supply substrate TW, the more accurately it is possible to control the range of the irradiation region where the UV light 50 is irradiated onto the adhesive tape 32 and the range of the mask region. However, similar to the light source unit 720 of the first embodiment, the light source unit 720B may be arranged apart from the light-transmitting member 712.

In addition, the light-transmitting member 712 and the light source unit 720B may be integrated. For example, the light source unit 720B may be a structure in which a plurality of LEDs is mounted on one surface of the light-transmitting member 712 in a matrix.

As shown in FIGS. 5A and 5B, the light source unit 720B includes the LED light source 725 and an outer frame 726 provided around the LED light source 725. In the present embodiment, although an example in which the outer shape of the light source unit 720B is circular is shown, the present disclosure is not limited to this example and may also be rectangular.

The LED light source 725 has a configuration in which the plurality of light-emitting regions 725a is arranged in a matrix on a substrate. A glass substrate, a quartz substrate, a resin substrate, a ceramic substrate, a metal substrate, and the like may be used as the substrate. Each of the plurality of light-emitting regions 725a is a region surrounded by the scanning line SL and the data line DL, and includes the LED element LD and the driving element DE that controls the LED element LD. For each LED element LD, it is preferable to use a MiniLED or MicroLED, which are smaller than a regular LED. The smaller the size of the LED element LD, the higher the arrangement density of the LED light source 725, and the irradiation range of the UV light 50 can be controlled more precisely.

The LED light source 725 can control the driving element DE by supplying various signals to the scanning line SL and the data line DL, and switch the LED element LD to an on state (lit state) or off state (unlit state). That is, when the LED element LD is in the on state, the light-emitting region 725a irradiates the UV light 50, and when the LED element LD is in the off state, the light-emitting region 725a does not irradiate the UV light 50. As described above, by controlling the on/off states of each light-emitting region 725a, a lit region ON (the region where the UV light 50 is irradiated) and an unlit region OFF (the region where the UV light 50 is not irradiated) of the LED light source 725 can be formed into a desired shape and range.

Similar to a known LED display, the LED light source 725 can individually control the on/off of each light-emitting region 725a, allowing the shape of the lit region ON to be formed into a circle, polygon, or any other shape. In addition, the present disclosure is not limited to this example, and the LED light source 725 can be divided into a plurality of blocks similar to known local dimming, and the on/off can be controlled for each block. As described above, according to the present embodiment, by controlling the lit region ON and the unlit region OFF of the LED light source 725, the UV light 50 can be selectively irradiated onto a desired region of the adhesive tape 32.

The outer frame 726 is a region surrounding the LED light source 725, and is provided with wiring for supplying signals to the scanning line SL and the data line DL, and a driving circuit for generating or controlling those signals. The driving circuit arranged in the outer frame 726 may be formed on the substrate through a semiconductor process or may be mounted as a semiconductor chip. Since no light-emitting region 725a is arranged in the outer frame 726, the outer frame 726 is a region that does not irradiate UV light, similar to the unlit region OFF. As shown in FIG. 5A, the outer frame 726 in the present embodiment overlaps the region of the adhesive tape 32 surrounding the semiconductor chip 33 and prevents the region from being irradiated with the UV light 50, thereby preventing a decrease in adhesive strength.

Furthermore, although a thin film transistor (TFT) is exemplified as the driving element DE in the present embodiment, the present disclosure is not limited to this example, and other driving elements may be used. In addition, although an active matrix type LED light source in which the driving element DE is arranged in each light-emitting region 725a is exemplified as the LED light source 725, a simple matrix type LED light source in which a light-emitting layer is sandwiched between the scanning line SL and the data line DL may be used.

### Fourth Embodiment

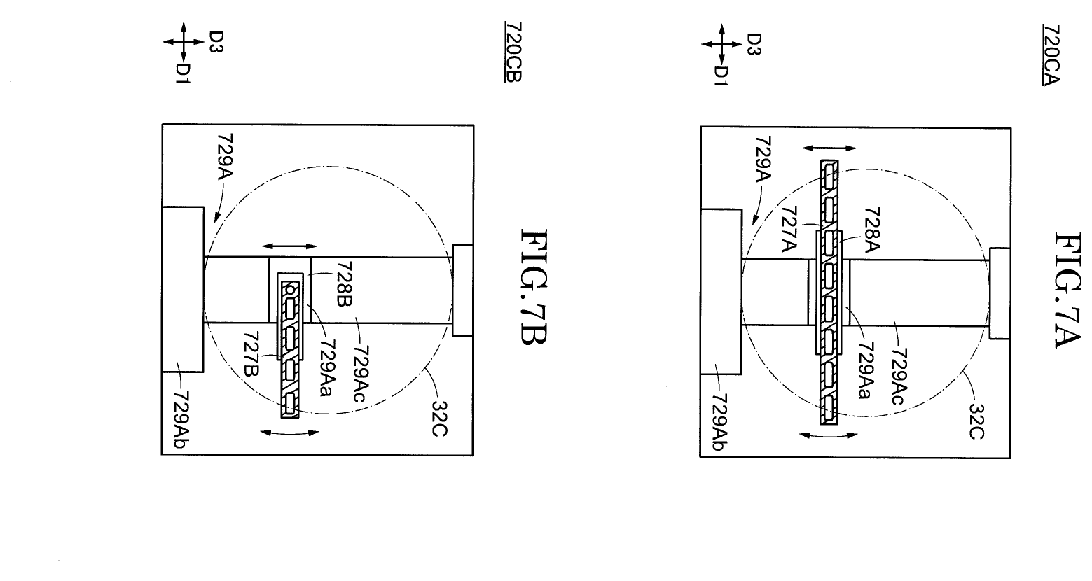

In the present embodiment, an example in which the configuration of the light source unit is different from that of the first embodiment will be described. Specifically, a light source unit 720C in the present embodiment can selectively irradiate the UV light 50 onto the adhesive tape 32 by controlling a movement range (movement range in a direction D3) of a linear light source 727. In this case, the direction D3 is a direction orthogonal to the direction D1 (left-right direction) and the direction D2 (up-down direction), and as shown in FIG. 6B, the direction D3 is a direction orthogonal to the direction in which the light source 727 is arranged in a plan view. A basic configuration of a UV light irradiation unit 700C of the present embodiment is similar to that of the UV light irradiation unit 700 of the first embodiment. Therefore, in the present embodiment, the explanation will focus on the parts of the configuration that are different from the first embodiment. For the same configuration as the UV light irradiation unit 700 of the first embodiment, redundant explanations may be omitted by using the same reference signs.

FIG. 6A is a schematic cross-sectional view showing a configuration of the UV light irradiation unit 700C according to an embodiment of the present disclosure. FIG. 6B is a plan view showing a configuration of the light source unit 720C according to an embodiment of the present disclosure. The light source unit 720C in the UV light irradiation unit 700C of the present embodiment includes the light source 727, a light source support unit 728, and a light source drive unit 729. However, the configuration of the UV light irradiation unit 700C is not limited to this example, and some components shown in FIG. 6A may be omitted, or other components may be added.

The light source 727 is a linear light source with the direction D1 as the longitudinal direction, and is composed of a UV light lamp or an LED that emits UV light. A length of the light source 727 in the longitudinal direction corresponds to a width (width in the direction D1) of the region occupied by the semiconductor chip 33. For example, if the semiconductor chip 33 is formed on a 300 mm wafer, the length of the light source 727 in the longitudinal direction is 300 mm to 320 mm.

As shown in FIG. 6A, the light source 727 moves directly below the light-transmitting member 712. The light-transmitting member 712 is arranged to form a flat surface for placing the supply substrate TW with the upper surface 712a of the light-transmitting member 712 and the upper surface 711b of the housing 711. In the present embodiment, since the distance between the light source 727 and the adhesive tape 32 of the supply substrate TW is short, the range of the irradiation region where the UV light 50 is irradiated onto the adhesive tape 32 can be accurately controlled. However, the light source 727 may be arranged apart from the light-transmitting member 712.

The light source support unit 728 is a pedestal to support the light source 727, and the lower end is connected to a moving portion 729a of the light source drive unit 729. The light source support unit 728 is configured to be movable in the direction D3 shown in FIG. 6B according to the movement of the moving portion 729a.

The light source drive unit 729 includes the moving portion 729a, a drive source 729b, and a rail portion 729c. For example, the drive source 729b includes a motor or gears, and drives the rail portion 729c. For example, the rail portion 729c includes a ball screw or linear guide, and linearly moves the moving portion 729a along the direction D3. The light source drive unit 729 controls the light emission of the light source 727 and the movement of the moving portion 729a. The moving portion 729a is movably connected in the direction D3 to the rail portion 729c of the light source drive unit 729 and has the function of moving the light source 727 in the direction D3 via the light source support unit 728 connected above.

In the present embodiment, the movement range of the light source 727 in the direction D3 can be controlled by the light source drive unit 729. For example, if only half of the semiconductor chip 33 on the supply substrate TW is used, the movement range of the moving portion 729a can be limited to half, so that the UV light 50 is selectively irradiated onto a region 32C of the adhesive tape 32 where the semiconductor chip 33 is adhered (see FIG. 6B). That is, the movement range of the moving portion 729a may be controlled so that a range 32Ca of the region 32C described above to be irradiated with the UV light 50 is half of the entire region 32C. Of course, when all the semiconductor chips 33 on the supply substrate TW are used, the moving portion 729a may be moved from one end to another so that the UV light 50 is irradiated over the entire region 32C on the adhesive tape 32. In addition, when one-quarter of the semiconductor chips 33 on the supply substrate TW are used, the UV light 50 may be selectively irradiated onto one-quarter of the entire region 32C on the adhesive tape 32.

As described above, in the present embodiment, by controlling the movement range of the moving portion 729a according to the usage amount of the semiconductor chip 33 adhered to the supply substrate TW, the UV light 50 can be selectively irradiated onto the adhesive tape 32 to selectively reduce the adhesive strength in the region 32C where the semiconductor chip 33 is adhered.

### First Modification

Although an example in which the entire light source 727 emits light collectively is shown in the example of FIG. 6A, the present disclosure is not limited to this example, and the light source 727 may be divided into multiple blocks and emit light in each block individually. For example, the light source 727 may be divided into two blocks in the longitudinal direction (direction D1) (that is, divided in half), and the light emission control of each block can be performed independently. In this case, it is possible to divide the region 32C shown in FIG. 6B into four folding fan-shaped regions and selectively reduce the adhesive strength. In addition, the divided driving of the light source 727 is not limited to the example of dividing into two blocks, but may be performed by dividing into three or more blocks. As described above, by dividing the light source 727 into n or more blocks in the longitudinal direction (direction D1) and independently controlling the light emission of each block, the region in the adhesive tape 32 where the adhesive strength is selectively reduced can be further subdivided.

In addition, as described above, when the light source 727 is divided into a plurality of blocks, each block may be independently movable. Specifically, by connecting the moving portion 729a to each block and moving each moving portion 729a independently, the UV light 50 can be selectively irradiated onto the adhesive tape 32. For example, when dividing the light source 727 into two blocks in the longitudinal direction (direction D1) and independently controlling the movement of each block, by moving only one side from one end to the other, the UV light 50 can be selectively irradiated onto one-half of the region 32C in the direction D1. Furthermore, by moving only one side from one end to the halfway position, the UV light 50 can be selectively irradiated onto one-quarter of the region 32C.

### Second Modification

Although the example in which the light source 727 is moved in the direction D3 is shown in the example shown in FIG. 6A, the present disclosure is not limited to this example, and it is also possible to drive the light source 727 to rotate with the vertical direction as an axis.

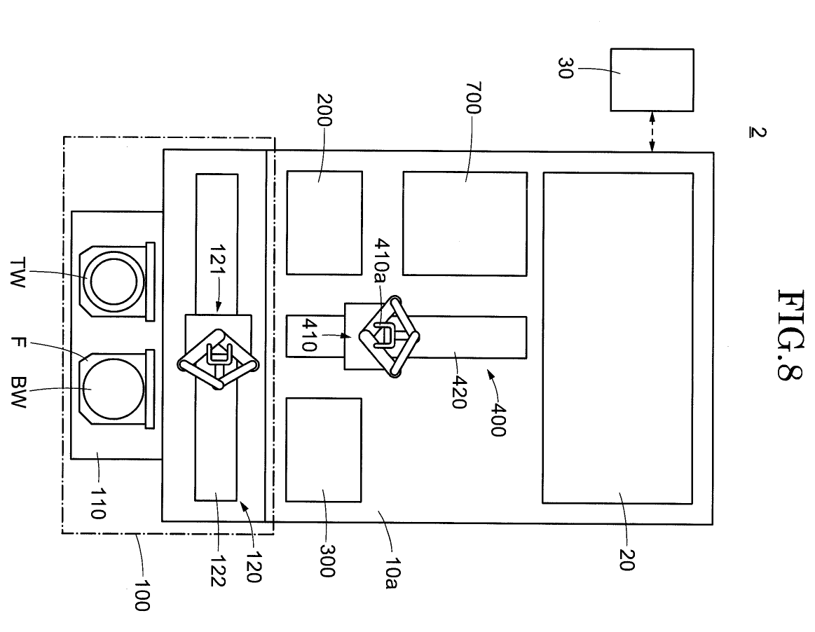

FIG. 7A is a plan view showing a configuration of a light source unit 720CA according to a modification of an embodiment of the present disclosure. As shown in FIG. 7A, in the light source unit 720CA, a light source 727A is rotatable in a direction of the arrow with the vertical direction (direction D2 shown in FIG. 6A) as an axis. Although an example in which the light source 727A rotates when a light source support unit 728A rotates with respect to a moving portion 729Aa is shown, the present disclosure is not limited to this example, and the light source 727A may be configured to rotate with respect to the light source support unit 728A. A light source drive unit 729A performs drive control to move the moving portion 729Aa in the direction D3 and also drive control to rotate the light source support unit 728A with the vertical direction as an axis.

In addition, FIG. 7B is a plan view showing a configuration of a light source unit 720CB according to a modification of an embodiment of the present disclosure. In the example shown in FIG. 7B, a length of a light source 727B in the longitudinal direction (direction D1) is half that of the example shown in FIG. 7A. That is, a length of the light source 727B in the longitudinal direction corresponds to the radius of the region 32C. In this case, the light source 727B is also configured to rotate in the direction of the arrow with the vertical direction (direction D2 shown in FIG. 6A) as an axis. Although an example in which the light source 727B rotates when a light source support unit 728B rotates with respect to a moving portion 729Aa is shown, the present disclosure is not limited to this example, and the light source 727B may be configured to rotate with respect to the light source support unit 728B.

According to the present modification, due to the rotation with the vertical direction as an axis (direction D2) in addition to the movement of the light source 727A and the light source 727B in the direction D3, the region in the adhesive tape 32 where the adhesive strength is selectively reduced can be set with greater flexibility.

### Fifth Embodiment

In the present embodiment, an example in which the configuration of the mounting system is different from that of the first embodiment will be described. Specifically, a mounting system 2 of the present embodiment does not include the activation processing unit 500 and the cleaning unit 600 that are included in the pretreatment apparatus 10 of the first embodiment, and a pretreatment apparatus 10a includes only the UV light irradiation unit 700. In the present embodiment, the explanation will focus on the parts of the configuration that are different from the first embodiment. For the same configuration as the mounting system 1 of the first embodiment, redundant explanations may be omitted by using the same reference signs.

FIG. 8 is a block diagram showing an overall configuration of the mounting system 2 according to an embodiment of the present disclosure. For example, the mounting system 2 is a system for mounting a semiconductor chip with bumps onto the semiconductor wafer. In FIG. 8, the pretreatment apparatus 10a is an apparatus for performing a UV light irradiation treatment to reduce or eliminate the adhesive strength by irradiating UV light onto the adhesive tape so that the semiconductor chip to be mounted can be easily picked up from the adhesive tape that supports the semiconductor chip. The bonding apparatus 20 mounts (places, loads, or temporarily bonds) the semiconductor chip received from the pretreatment apparatus 10a onto the mounting substrate.

The pretreatment apparatus 10a of the present embodiment includes the load/unload unit 100, the supply buffer unit 200, the discharge buffer unit 300, the workpiece transport unit 400, and the UV light irradiation unit 700. However, the configuration of the pretreatment apparatus 10a is not limited to this example, and some components shown in FIG. 8 may be omitted, or other components may be added. The specific operations of the load/unload unit 100, the supply buffer unit 200, the discharge buffer unit 300, the workpiece transport unit 400, and the UV light irradiation unit 700 are as described in the first embodiment, so the explanation here is omitted.

According to the present embodiment, similar to the first embodiment, when UV light is irradiated onto the resin film with the semiconductor chip with bumps adhered to reduce the adhesive strength, the influence of oxygen inhibition can be suppressed.

Although the UV light irradiation apparatus according to an embodiment of the present disclosure and the mounting system including the same have been described above with reference to the drawings, the present disclosure is not limited to the embodiments described above and can be modified as appropriate without departing from the spirit of the present disclosure. For example, the addition, deletion, or design change of components as appropriate by those skilled in the art based on each embodiment are also included in the scope of the present disclosure as long as they are provided with the gist of the present disclosure. Furthermore, the configurations according to each of the embodiments described above can be appropriately combined and implemented as long as no contradiction is caused, and technical matters common to the embodiments are included in each configuration even if not explicitly stated.

Further, it is understood that, even if the effect is different from those provided by each of the above-described embodiments, the effect obvious from the description in the specification or easily predicted by persons ordinarily skilled in the art is apparently derived from the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A UV light irradiation apparatus for irradiating UV light onto a resin film having multiple electronic components adhered to a first surface of the resin film, the UV light irradiation apparatus comprising:
a support stage for supporting the resin film;
a light source portion irradiating UV light onto a second surface of the resin film opposite the first surface; and
a mask portion disposed between the resin film and the light source portion and shielding a part of the UV light.

2. The UV light irradiation apparatus according to claim 1, wherein the support stage includes a light-transmissive member transmitting the UV light, and
the mask portion is disposed between the light-transmissive member and the resin film.

3. The UV light irradiation apparatus according to claim 1, wherein the mask portion has an opening, and
a position of the opening can be changed by rotating the mask portion about a vertical axis.

4. The UV light irradiation apparatus according to claim 1, wherein the mask portion includes a liquid crystal shutter, and
a position of a UV light shielding area can be changed by controlling the liquid crystal shutter.

5. A UV light irradiation apparatus for irradiating UV light onto a resin film having multiple electronic components adhered to a first surface of the resin film, the UV light irradiation apparatus comprising:
a support stage for supporting the resin film; and
a light source portion selectively irradiating UV light onto a desired area of a second surface opposite the first surface of the resin film.

6. The UV light irradiation apparatus according to claim 5, wherein the light source portion includes a plurality of light emitting diodes emitting the UV light, and
a position of a UV light irradiation area can be changed by controlling the plurality of light emitting diodes.

7. The UV light irradiation apparatus according to claim 5, wherein the light source portion includes a light source extending in a first direction and a moving mechanism capable of moving the light source in a second direction perpendicular to the first direction in a planar view.

8. The UV light irradiation apparatus according to claim 7, wherein the light source portion includes a plurality of the light sources, and
the moving mechanism is capable of moving each of the plurality of light sources independently.

9. The UV light irradiation apparatus according to claim 5, wherein the light source portion is configured to rotate about a vertical axis.

10. A mounting system comprising a pretreatment apparatus including the UV light irradiation apparatus according to claim 1, and a bonding apparatus mounting an electronic component received from the pretreatment apparatus onto a substrate.
